(19) United States
(12) Patent Application Publication
(10) Pub. No.: US 2023/0187437 A1
(43) Pub. Date: Jun. 15, 2023

(54) SEMICONDUCTOR DEVICE

(71) Applicant: FUJI ELECTRIC CO., LTD., Kawasaki-shi (JP)

(72) Inventor: Masaharu YAMAJI, Matsumoto-city (JP)

(73) Assignee: FUJI ELECTRIC CO., LTD., Kawasaki-shi (JP)

(21) Appl. No.: 17/975,207

(22) Filed: Oct. 27, 2022

(30) Foreign Application Priority Data
Dec. 14, 2021 (JP) 2021-202281

(51) Int. Cl. H01L 27/02

(52) U.S. Cl. CPC H01L 27/0296; H01L 27/0255; H01L 27/0288

(57) ABSTRACT

A semiconductor device includes: a semiconductor base body; a first region of a first conductivity type selectively provided in an upper part of the semiconductor base body; a second region of a second conductivity type provided in contact with the first region in the upper part of the semiconductor base body; a third region of the second conductivity type provided away from the second region in the upper part of the semiconductor base body; a fourth region of the second conductivity type provided between the second region and the third region in the upper part of the semiconductor base body; a first isolation region provided between the second region and the fourth region; and a second isolation region provided between the third region and the fourth region.

### CROSS-REFERENCE TO RELATED APPLICATION

This application claims benefit of priority under 35 USC 119 based on Japanese Patent Application No. 2021-202281 filed on Dec. 14, 2021, the entire contents of which are incorporated by reference herein.

### BACKGROUND OF THE INVENTION

### 1. Field of the Invention

The present invention relates to semiconductor devices.

### 2. Description of the Related Art

A switching power supply device, e.g., an LLC current resonant converter IC includes a startup element of a startup circuit connected to a high voltage input terminal (VH terminal) to which high voltage is input from an AC input line via a diode bridge, a high side circuit (high side gate driver circuit) connected to a high voltage VB terminal and a VS terminal to drive the gate of a high side power switching element of a half-bridge circuit, a level shift element, and the like (see PCIM Asia2012. A New 600V-Class Power Management IC Realizing a System Downsizing for Current Resonant Type Converters).

The startup element is a switching device that charges an external VCC power supply capacitor at power-on to start up a VCC power supply system circuit, and is generally constituted by a high voltage junction field effect transistor (JFET) or metal oxide semiconductor field effect transistor (MOSFET).

The high side circuit includes a level shift circuit, a latch circuit, a UVLO circuit, a gate driver circuit, and the like, and is surrounded by a high voltage junction termination (HVJT) region. In order to convert to a voltage level between a high side power supply potential VB and a high side reference potential VS generated by a bootstrap circuit, a logic level of an output to a HO terminal is switched by on/off operations of two level shift elements for SET/RESET that receive an input signal from a microcomputer to perform turn-on/turn-off control of the gate of the high side power switching element of the half-bridge circuit. A commonly used element isolation method is self-isolation or epitaxial (EPI) junction isolation, but converter ICs adopting dielectric isolation using a trench oxide film or the like are also available.

In recent years, there have been increased demands for lower prices of communication devices, home appliances, and the like, and a chip shrink technology has been required in which a switching power supply device itself is also achieved in a smaller chip size. Therefore, in conventional LLC current resonant converter ICs, a control chip having a digital control function and a trimming function is fabricated by a micro process using a 0.13-μm rule or the like, whereas high voltage devices such as a startup element, a high side circuit, and a level shift element are fabricated on a separate chip based on a large process rule, as a result of which multi-chip configurations in which a plurality of chips are arranged on the same die pad have become a mainstream.

JP 6008054 B2 discloses the formation of a p isolation diffusion region between PMOS and NMOS transistors in a high side region. JP 5293831 B2 discloses the formation of a p⁻ region between a high voltage MOSFET and a VS reference potential region.

### SUMMARY OF THE INVENTION

However, when forming a startup element and a high side circuit on the same high breakdown voltage chip, the startup element and the high side circuit, respectively, are connected to a VH terminal and a VB terminal having different high-voltage behaviors in operations such as charging and switching. Therefore, they cannot be formed in the same voltage blocking structure, and are arranged in separate regions isolated by a ground potential region. This is a hindrance to shrinkage in chip size.

In view of the above problem, it is an object of the present invention to provide a semiconductor device that, when forming a plurality of structures having high voltage behaviors independent from each other on the same chip, allows for reduction (shrinkage) in chip size.

An aspect of the present invention inheres in a semiconductor device including: a semiconductor base body; a first region of a first conductivity type selectively provided in an upper part of the semiconductor base body; a second region of a second conductivity type provided in contact with the first region in the upper part of the semiconductor base body; a third region of the second conductivity type provided away from the second region in the upper part of the semiconductor base body; a fourth region of the second conductivity type provided between the second region and the third region in the upper part of the semiconductor base body; a first isolation region provided between the second region and the fourth region; and a second isolation region provided between the third region and the fourth region.

### BRIEF DESCRIPTION OF THE DRAWINGS

FIG. 1 is a circuit diagram of a semiconductor device according to a first embodiment;

FIG. 2 is a plan view of the semiconductor device according to the first embodiment;

FIG. 3 is a sectional view taken along line A-A′ of FIG. 2;

FIG. 4 is a plan view of a semiconductor device according to a comparative example;

FIG. 5 is a plan view of a semiconductor device according to a second embodiment;

FIG. 6 is a sectional view taken along line A-A′ of FIG. 5;

FIG. 7 is a plan view of a semiconductor device according to a third embodiment;

FIG. 8 is a sectional view taken along line A-A′ of FIG. 7;

FIG. 9 is a plan view of a semiconductor device according to a fourth embodiment;

FIG. 10 is a sectional view taken along line A-A′ of FIG. 9;

FIG. 11 is a plan view of a semiconductor device according to a fifth embodiment;

FIG. 12 is a plan view of a semiconductor device according to a sixth embodiment;

FIG. 13 is a sectional view taken along line A-A′ of FIG. 12;

FIG. 14 is a sectional view of a semiconductor device according to another embodiment; and

FIG. 15 is another sectional view of the semiconductor device according to the other embodiment.

### DETAILED DESCRIPTION

With reference to the Drawings, first to sixth embodiments of the present invention will be described below.

In the Drawings, the same or similar elements are indicated by the same or similar reference numerals. The Drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions.

The first to third embodiments described below merely illustrate schematically devices and methods for specifying and giving shapes to the technical idea of the present invention, and the span of the technical idea is not limited to materials, shapes, structures, and relative positions of elements described herein.

In the Specification, a “carrier supply region” means a semiconductor region which supplies majority carriers as a main current. The carrier supply region is assigned to a semiconductor region which will be a source region in a field-effect transistor (FET) or a static induction transistor (SIT), an emitter region in an insulated-gate bipolar transistor (IGBT), and an anode region in a static induction (SI) thyristor or a gate turn-off (GTO) thyristor.

A “carrier reception region” means a semiconductor region which receive the majority carriers as the main current. The carrier reception region is assigned to a semiconductor region which will be the drain region in the FET or the SIT, the collector region in the IGBT, and the cathode region in the SI thyristor or GTO thyri stor.

In the Specification, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

In the Specification, there is exemplified a case where a first conductivity-type is an p-type and a second conductivity-type is a n-type. However, the relationship of the conductivity-types may be inverted to set the first conductivity-type to the n-type and the second conductivity-type to the p-type. Further, a semiconductor region denoted by the symbol “n” or “p” attached with “+” indicates that such semiconductor region has a relatively high impurity concentration as compared to a semiconductor region denoted by the symbol “n” or “p” without “+”. A semiconductor region denoted by the symbol “n” or “p” attached with “−” indicates that such semiconductor region has a relatively low impurity concentration as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration. Moreover, the members and the regions that are limited by adding “first conductivity-type” and “second conductivity-type” in the following description indicate the members and the regions formed of semiconductor materials without particular obvious limitations.

### First Embodiment

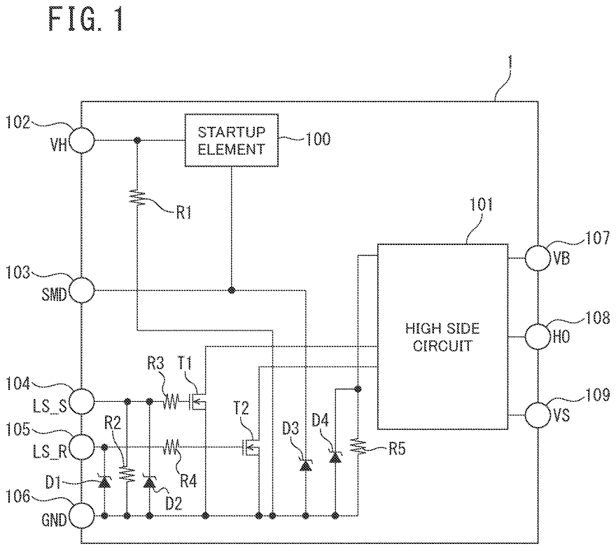

As an example of a semiconductor device according to a first embodiment, a high voltage integrated circuit (HVIC) including a startup element 100, a high potential side circuit (high side circuit) 101, and level shift elements T1 and T2 is illustrated in FIG. 1. The semiconductor device according to the first embodiment includes a VH terminal 102, an SMD terminal 103, an LS_S terminal 104, an LS_R terminal 105, a GND terminal 106, a VB terminal 107, an HO terminal 108, and a VS terminal 109.

The startup element 100 is an element that constitutes a part of a startup circuit for use in a switching power supply device. The startup element 100 is connected to the VH terminal 102 and the SMD terminal 103. A VH potential (first potential), which is a high potential, is applied to the VH terminal 102 from an AC input line via a diode bridge. The SMD terminal 103 is connected to an external startup circuit. The startup element 100 charges an external VCC power supply capacitor via the SMD terminal 103 according to the VH potential applied from the VH terminal 102 at power on to start up a VCC power supply system circuit.

The startup element 100 is constituted by, for example, a junction field effect transistor (JFET). A drain of the JFET being the startup element 100 is connected to the VH terminal 102, and a source of the JFET is connected to the SMD terminal 103. Note that the startup element 100 may be constituted by a MOSFET or the like other than the JFET.

A point between the startup element 100 and the VH terminal 102 is connected to the GND terminal 106 via a resistor R1. A cathode of a protection diode D3 is connected to the startup element 100 and the SMD terminal 103. An anode of the protection diode D3 is connected to the GND terminal 106.

The level shift elements T1 and T2 are composed of, for example, high voltage n-channel MOSFETs. Drains of the level shift elements T1 and T2, respectively, are connected to the high side circuit 101. Sources of the level shift elements T1 and T2, respectively, are connected to the GND terminal 106. A gate of the level shift element T1 is connected to the LS_S terminal 104 via a resistor R3. A gate of the level shift element T2 is connected to the LS_R terminal 105 via a resistor R4.

The level shift elements T1 and T2 are elements for transmitting signals between an external low potential side circuit (low side circuit) and the high side circuit 101. The level shift element T1 converts an on/off signal for setting a GND potential reference input from the external low side circuit via the LS_S terminal 104 to an on/off signal for setting a VS potential reference, and transmits to the high side circuit 101. The level shift element T2 converts an on/off signal for resetting a GND potential reference input from the external low side circuit via the LS_R terminal 105 to an on/off signal for resetting a VS potential reference, and transmits to the high side circuit 101.

Between the resistor R3 and the LS_S terminal 104 connected to the gate of the level shift element T1 are connected one end of a resistor R2 and a cathode of a protection diode D2, respectively. The other end of the resistor R2 and an anode of the protection diode D2, respectively, are connected to the GND terminal 106. Between the resistor R4 and the LS_R terminal 105 connected to the gate of the level shift element T2 is connected a cathode of a protection diode D1. An anode of the protection diode D1 is connected to the GND terminal 106.

The high side circuit 101 is connected to the VB terminal 107, the HO terminal 108, and the VS terminal 109. The VB terminal 107 receives a VB potential (second potential) that is a power supply potential and that is a maximum potential of the high side circuit 101. The VS terminal 109 receives a VS potential that is a minimum potential of the high side circuit 101 and that is approximately 15 V lower than the VB potential. The HO terminal 108 is connected to a gate of a high potential side power switching element of a power conversion unit in which the high potential side power switching element is connected to a low potential side power switching element. The VS terminal 109 is connected to a connection point between the high potential side power switching element and the low potential side power switching element. The VS potential fluctuates between high potential of the high potential side power switching element and low potential of the low potential side power switching element. Therefore, the VB potential also fluctuates with the fluctuation of the VS potential. The power switching elements are constituted by, for example, IGBTs, MOSFETs, or the like.

Although not illustrated in the drawing, the high side circuit 101 includes, for example, a level shift resistor, a level shift circuit, a latch circuit, a UVLO circuit, and a gate driver circuit. The gate driver circuit includes a CMOS circuit constituted by, for example, an nMOS transistor and a pMOS transistor in an output stage. The high side circuit 101 uses the VS potential applied to the VS terminal 109 as a reference potential and the VB potential applied to the VB terminal 107 as a power supply potential. The high side circuit 101 outputs an output signal HO to the HO terminal 108 according to on/off signals from the level shift elements T1 and T2 to drive the gate of the power switching element connected to the HO terminal 108.

One end of a resistor R5 and a cathode of a protection diode D4 are connected to the high side circuit 101. The other end of the resistor R5 and an anode of the protection diode D4 are connected to the GND terminal 106.

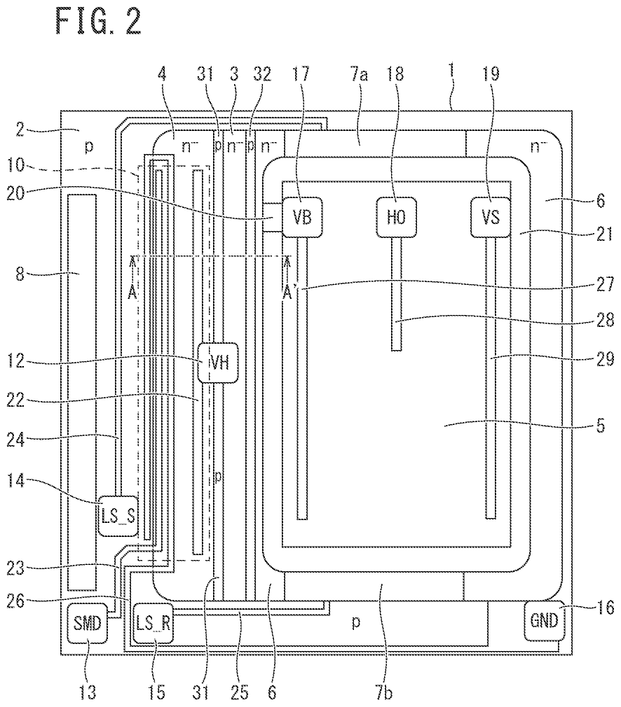

FIG. 2 is a plan view illustrating the configuration of the semiconductor device according to the first embodiment illustrated in FIG. 1. As illustrated in FIG. 2, the semiconductor device according to the first embodiment includes a startup element 10, a high potential side circuit region (high side circuit region) 5, and a protection element region 8 that are provided on the same high voltage semiconductor chip (p-type semiconductor base body) 1. The startup element 10 and the high side circuit region 5, respectively, correspond to the startup element 100 and the high side circuit 101 illustrated in FIG. 1. The protection element region 8 illustrated in FIG. 2 is a region formed with the protection diodes D1 to D5, the resistors R1 to R5, and the like illustrated in FIG. 1.

The p-type semiconductor base body 1 has, for example, a rectangular planar shape. The high side circuit region 5 is provided on a right side from a center of the rectangle made by the p-type semiconductor base body 1. The high side circuit region 5 has a substantially rectangular planar shape. The startup element 10 is provided on a left side of the rectangle made by the p-type semiconductor base body 1. The startup element 10 is provided so as to extend in parallel to a left side of the rectangle made by the high side circuit region 5. The protection element region 8 is provided further to the left side than the startup element 10 on the rectangle made by the p-type semiconductor base body 1. The protection element region 8 is provided in parallel to a longitudinal direction of the startup element 10 and so as to linearly extend along the left side of the rectangle made by the p-type semiconductor base body 1.

Although illustrations are omitted, the high side circuit region 5 is provided with various elements such as the nMOS transistor and the pMOS transistor constituting the CMOS circuit of the output stage. Around the high side circuit region 5 is provided an annular n⁻-type voltage blocking area 6 so as to surround the high side circuit region 5. The voltage blocking area 6 is constituted by, for example, a high voltage junction termination (HVJT) region. The voltage blocking area 6 is provided with level shift elements 7a and 7b. The level shift elements 7a and 7b are constituted by, for example, high voltage n-channel MOSFETs. The voltage blocking areas of the level shift elements 7a and 7b are commonized with the voltage blocking area 6.

The semiconductor device according to the first embodiment includes a VH pad 12, an SMD pad 13, an LS_S pad 14, an LS_R pad 15, a GND pad 16, a VB pad 17, an HO pad 18, and a VS pad 19 each constituting an electrode pad. The VH pad 12, the SMD pad 13, the LS_S pad 14, the LS_R pad 15, the GND pad 16, the VB pad 17, the HO pad 18, and the VS pad 19, respectively, correspond to the VH terminal 102, the SMD terminal 103, the LS_S terminal 104, the LS_R terminal 105, the GND terminal 106, the VB terminal 107, the HO terminal 108, and VS terminal 109 illustrated in FIG. 1.

The VH pad 12 is provided above the startup element 10 in the vicinity of a right side of a longitudinal center of the startup element 10. A metal wiring 22 is connected to the VH pad 12. The metal wiring 22 extends along the longitudinal direction of the startup element 10 and is electrically connected to a drain region of the startup element 10 via a via of an underlayer of the metal wiring 22.

The SMD pad 13 is provided above a ground potential region 2 in a lower left region of the rectangle made by the p-type semiconductor base body 1. A metal wiring 23 is connected to the SMD pad 13. The metal wiring 23 extends along the longitudinal direction of the startup element 10 and is electrically connected to a source region of the startup element 10 via a via of an underlayer of the metal wiring 23.

The LS_S pad 14 is provided above the ground potential region 2 between the protection element region 8 and the startup element 10 in the vicinity of a lower left of the rectangle made by the p-type semiconductor base body 1. A metal wiring 24 is connected to the LS_S pad 14. The metal wiring 24 extends between the protection element region 8 and the startup element 10 and is connected to the level shift element 7a.

The LS_R pad 15 is provided above the ground potential region 2 so as to be adjacent to a right side of the SMD pad 13 in the vicinity of the lower left of the rectangle made by the p-type semiconductor base body 1. A metal wiring 25 is connected to the LS_R pad 15. The metal wiring 25 is connected to the level shift element 7b.

The GND pad 16 is provided above the ground potential region 2 in a lower right region of the rectangle made by the p-type semiconductor base body 1. A metal wiring 26 is connected to the GND pad 16. The metal wiring 26 extends along a lower side of the rectangle made by the p-type semiconductor base body 1, passes through between the SMD pad 13 and the LS_R pad 15, and extends along the longitudinal direction of the startup element 10. Additionally, the metal wiring 26 is folded back into a U-shape at an end portion of the metal wiring 23 and extends along the longitudinal direction of the startup element 10. The metal wiring 26 is electrically connected to the ground potential region 2 and a gate electrode of the startup element 10 via a via of an underlayer of the metal wiring 26.

The VB pad 17 is provided above the high side circuit region 5. A metal wiring 20 and a metal wiring 27 are connected to the VB pad 17. The metal wiring 20 is electrically connected to an annular metal wiring 21 on a lower layer than the metal wiring 20 via a via of an underlayer of the metal wiring 20. The metal wiring 21 is connected to the high side circuit region 5 on a lower layer than the metal wiring 21 via a via of an underlayer of the metal wiring 21. The metal wiring 27 is electrically connected to necessary portions of various elements included in the high side circuit region 5 via a via of an underlayer of the metal wiring 27.

The HO pad 18 is provided above the high side circuit region 5. A metal wiring 28 is connected to the HO pad 18. The metal wiring 28 is electrically connected to necessary portions of the various elements included in the high side circuit region 5 via a via of an underlayer of the metal wiring 28.

The VS pad 19 is provided above the high side circuit region 5. A metal wiring 29 is connected to the VS pad 19. The metal wiring 29 is electrically connected to necessary portions of the various elements included in the high side circuit region 5 via a via of an underlayer of the metal wiring 29.

The startup element 10 is provided in an n⁻-type voltage blocking area 4. The voltage blocking area 6 on the high side circuit 101 side and the voltage blocking area 4 on the startup element 10 side are surrounded by the p-type ground potential region 2. Between the voltage blocking area 6 on the high side circuit 101 side and the voltage blocking area 4 on the startup element 10 side are provided double isolation regions (first and second isolation regions) 31 and 32. The isolation regions 31 and 32 are composed of, for example, p-type diffusion layers. FIG. 2 exemplifies the isolation regions 31 and 32 that have a linear planar shape extending in a vertical direction of FIG. 2. Longitudinal end portions of the isolation regions 31 and 32 are coincident with outer peripheral end portions of the voltage blocking areas 4 and 6 and are in contact with the ground potential region 2.

Between the isolation regions 31 and 32 is provided an n⁻-type floating potential region 3. The floating potential region 3 has a linear planar shape extending in parallel to the isolation regions 31 and 32. Longitudinal end portions of the floating potential region 3 are in contact with the ground potential region 2. The floating potential region 3 is not fixed at a specific potential, but is at floating potential. Not being fixed at a specific potential means that, for example, a specific potential such as the VS potential is not applied during normal operation.

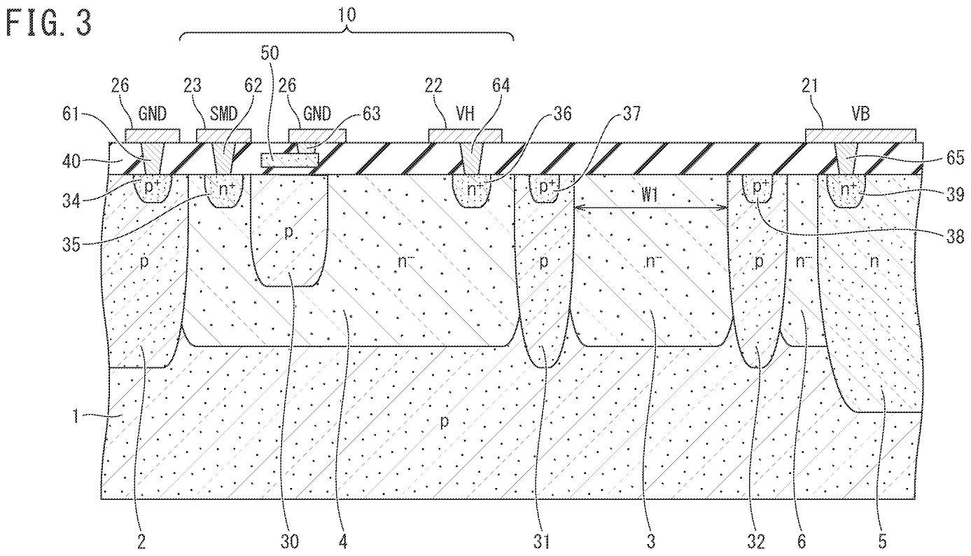

FIG. 3 is a sectional view taken along line A-A′ passing through the startup element 10 of FIG. 2. As illustrated in FIG. 3, an insulating film 40 is provided on an upper surface of the p-type semiconductor base body 1. The insulating film 40 is not illustrated in FIG. 2. The p-type semiconductor base body 1 is formed by, for example, a silicon (Si) substrate, but not limited thereto, and may be formed by a semiconductor substrate made of, for example, silicon carbide (SiC), gallium nitride (GaN), gallium arsenide (GaAs), or the like. Alternatively, the p-type semiconductor base body 1 may be formed by a p-type epitaxial layer provided on a semiconductor substrate.

In an upper part of the p-type semiconductor base body 1 is provided the p-type ground potential region (first region) 2. In an upper part of the ground potential region 2 is provided a p⁺-type contact region 34 having a higher impurity concentration than the ground potential region 2. The contact region 34 is connected to the metal wiring 26 on the insulating film 40 via a via 61 penetrating through the insulating film 40. A GND potential (e.g., 0 V) is applied to the contact region 34 via the via 61, the metal wiring 26, and the GND pad 16 to fix the contact region 34 at the GND potential.

In the upper part of the p-type semiconductor base body 1 is provided the n⁻-type voltage blocking area (second region) 4 in contact with the ground potential region 2. In an upper part of the voltage blocking area 4 on the ground potential region 2 side is provided a source region (seventh region) 35 having a higher impurity concentration than the voltage blocking area 4, which source region 35 is an n⁺-type carrier supply region of the startup element 10. The source region 35 is connected to the metal wiring 23 on the insulating film 40 via a via 62 penetrating through the insulating film 40, and is electrically connected to the SMD pad 13.

In the upper part of the voltage blocking area 4 is provided a p-type gate region 30 of the startup element 10 separated from the source region 35. Note that depending on the type of the startup element 10, the gate region 30 may be not provided at this position. For example, the gate region 30 is provided in a vertical pinch-off structure, as illustrated in FIG. 3, but may be not provided at the above position in a structure in which the planar shape of the source and gate regions of the startup element 10 is gear-shaped. Above the gate region 30 is provided a gate electrode 50 of the startup element 10 via a gate insulating film that is a part of the insulating film 40, which gate electrode 50 is embedded in the insulating film 40. The gate electrode 50 is connected to the metal wiring 26 on the insulating film 40 via a via 63 penetrating through the insulating film 40 on the gate electrode 50. The GND potential is applied to the gate electrode 50 via the via 63, the metal wiring 26, and the GND pad 16.

In the upper part of the voltage blocking area 4 is provided a drain region (eighth region) 36 that is separated from the source region 35 and the gate region 30 and that has a higher impurity concentration than the voltage blocking area 4, which drain region 36 is an n⁺-type carrier reception region of the startup element 10. The drain region 36 is connected to the metal wiring 22 on the insulating film 40 via a via 64 penetrating through the insulating film 40. A VH potential of, for example, approximately several hundred V, which is higher than the GND potential, is applied to the drain region 36 via the via 64, the metal wiring 22, and the VH pad 12.

In the startup element 10, the VH potential is applied to the drain region 36, and current flows from the drain region 36 to the source region 35 via the voltage blocking area 4 serving as a drift region. The current flowing through the source region 35 charges the external VCC power supply capacitor via the SMD pad 13 to start up the VCC power supply system circuit. When the potential of the voltage blocking area 4 rises, a depletion layer expands from a pn junction between the voltage blocking area 4 and the gate region 30, and the voltage blocking area 4 below the gate region 30 is pinched off. This causes the startup element 10 to go into an off state.

In the upper part of the p-type semiconductor base body 1 is provided the isolation region (first isolation region) 31 in contact with the voltage blocking area 4. The isolation region 31 is constituted by a p-type diffusion region. The isolation region 31 has a depth greater than a depth of the voltage blocking area 4 and the floating potential region 3. The isolation region 31 has a bottom portion reaching the p-type semiconductor base body 1. The isolation region 31 is electrically connected to the GND potential via the p-type semiconductor base body 1.

In an upper part of the isolation region 31 is provided a p⁺-type inversion prevention region 37 having a higher impurity concentration than the isolation region 31. The inversion prevention region 37 is not illustrated in FIG. 2, but may extend linearly along the linear planar shape of the isolation region 31. The impurity concentration of the inversion prevention region 37 is adjusted to a concentration level that does not cause complete depletion when the VH voltage, which is a high voltage, is applied to the adjacent voltage blocking area 4. The inversion prevention region 37 serves to prevent an inversion layer from being formed in the isolation region 31 due to a surface charge or the like in the isolation region 31.

In the upper part of the p-type semiconductor base body 1 is provided the n⁻-type floating potential region (fourth region) 3 at floating potential in contact with the isolation region 31. A width W1 of the floating potential region 3 is preferably, for example, approximately from 50 μm to 100 μm. The floating potential region 3 may have the same depth as that of the voltage blocking area 6. The floating potential region 3 may have the same impurity concentration as that of the voltage blocking area 6.

In the upper part of the p-type semiconductor base body 1 is provided the isolation region (second isolation region) 32 in contact with the floating potential region 3. The isolation region 32 is constituted by a p-type diffusion region, as in the isolation region 31. The isolation region 32 may have an impurity concentration that is the same as or different from the impurity concentration of the isolation region 31. The isolation region 32 has a depth greater than a depth of the floating potential region 3 and the voltage blocking area 6. The depth of the isolation region 32 may be the same as or different from the depth of the isolation region 31. The isolation region 32 has a bottom portion reaching the p-type semiconductor base body 1. The isolation region 32 is electrically connected to the GND potential via the p-type semiconductor base body 1.

In an upper part of the isolation region 32 is provided a p⁺-type inversion prevention region 38 having a higher impurity concentration than the isolation region 32. The inversion prevention region 38 is not illustrated in FIG. 2, but may extend linearly along the linear planar shape of the isolation region 32. The impurity concentration of the inversion prevention region 38 is adjusted to a concentration level that does not cause complete depletion when the VB voltage, which is a high voltage, is applied to the adjacent voltage blocking area 6. The inversion prevention region 38 serves to prevent an inversion layer from being formed in the isolation region 32 due to a surface charge or the like in the isolation region 32.

In the upper part of the p-type semiconductor base body 1 is provided the n-type high side circuit region (third region) 5 on a side of the isolation region 32 opposite to the floating potential region 3. In the upper part of the p-type semiconductor base body 1 is provided the n⁻-type voltage blocking area (sixth region) 6 having a lower impurity concentration than the high side circuit region 5 between the isolation region 32 and the high side circuit region 5. Besides at least between the isolation region 32 and the high side circuit region 5, the voltage blocking area 6 only needs to be provided so as to surround the high side circuit region 5. The voltage blocking area 6 may be not provided between the isolation region 32 and the high side circuit region 5. When the voltage blocking area 6 is not provided between the isolation region 32 and the high side circuit region 5, the isolation region 32 and the high side circuit region 5 may be in contact with each other. In an upper part of the high side circuit region 5 is provided an n⁺-type contact region 39 having a higher impurity concentration than the high side circuit region 5. The contact region 39 is connected to the metal wiring 21 on the insulating film 40 via a via 65 penetrating through the insulating film 40. The VB potential higher than the GND potential is applied to the contact region 39 via the via 65, the metal wiring 21, and the VB pad 17. The VB potential is applied separately and independently in a separate system from the VH potential. The VB potential may be equal to the VH potential, or may be lower or higher than the VH potential.

In other words, the semiconductor device according to the first embodiment has the structure in which the startup element 10 is provided in a part of the n⁻-type voltage blocking areas 4 and 6 surrounding the high side circuit region 5, the high side circuit region 5 and the startup element 10 are isolated by the at least double isolation regions 31 and 32, and the floating potential region 3 at floating potential is provided between the isolation regions 31 and 32.

In the startup element 10 of the semiconductor device according to the first embodiment, when the VH potential being a high voltage of several hundred V is applied to the drain region 36 of the startup element 10 via the VH pad 12, the metal wiring 22, and the via 64, a depletion layer expands from a pn junction between the isolation region 31 and the voltage blocking area 4, a lower part of the isolation region 31 is depleted, and an electric field is also applied to the floating potential region 3. The floating potential region 3 goes into an intermediate potential state between a potential of the voltage blocking area 4 on the startup element 10 side and a potential of the voltage blocking area 6 on the high side circuit region 5 side, allowing breakdown voltage to be maintained in a lower voltage state than in the voltage blocking area 4 on the startup element 10 side without causing any local electric field concentration from the ground potential region 2 on an outer periphery to a high potential region.

Additionally, in the high side circuit region 5 of the semiconductor device according to the first embodiment, when the VB potential being a high voltage is applied to the contact region 39 in the upper part of the high side circuit region 5 via the VB pad 17, the metal wiring 21, and the via 65, a depletion layer expands from a pn junction between the isolation region 32 and the voltage blocking area 6, a lower part of the isolation region 32 is depleted, and an electric field is also applied to the floating potential region 3. The floating potential region 3 goes into an intermediate potential state between the potential of the voltage blocking area 4 on the startup element 10 side and the potential of the voltage blocking area 6 on the high side circuit region 5 side, allowing breakdown voltage to be maintained in a lower voltage state than in the voltage blocking area 6 on the high side circuit region 5 side.

In addition, even when the VB potential being a high voltage is applied to the contact region 39 in the upper part of the high side circuit region 5 at the same time as the VH potential being a high potential is applied to the drain region 36 of the startup element 10 of the semiconductor device according to the first embodiment, the lower part of each of the isolation regions 31 and 32 is depleted, and an electric field is applied even to the floating potential region 3. The floating potential region 3 can maintain breakdown voltage in a lower voltage state than in the voltage blocking area 4 on the startup element 10 side and the voltage blocking area 6 on the high side circuit region 5 side.

Furthermore, in the semiconductor device according to the first embodiment, by isolating the voltage blocking area 4 on the startup element 10 side and the voltage blocking area 6 on the high side circuit region 5 side by the at least double isolation regions 31 and 32 and setting the width W1 of the floating potential region 3 to 50 μm or more, a parasitic npn bipolar transistor constituted by an n-type well region that is the high side circuit region 5, the p-type semiconductor base body 1, and the n⁻type voltage blocking area 4 serves as a wide base transistor to keep gain small even when an overshoot or undershoot voltage noise due to switching or an external surge is momentarily applied to the VH pad 12 and the VB pad 17. This can suppress operation of the parasitic npn bipolar transistor against voltage fluctuations of the VH pad 12 and the VB pad 17, allowing for suppressed thermal runaway destruction. Thus, a high voltage chip with high noise resistance can be achieved at low cost.

### COMPARATIVE EXAMPLE

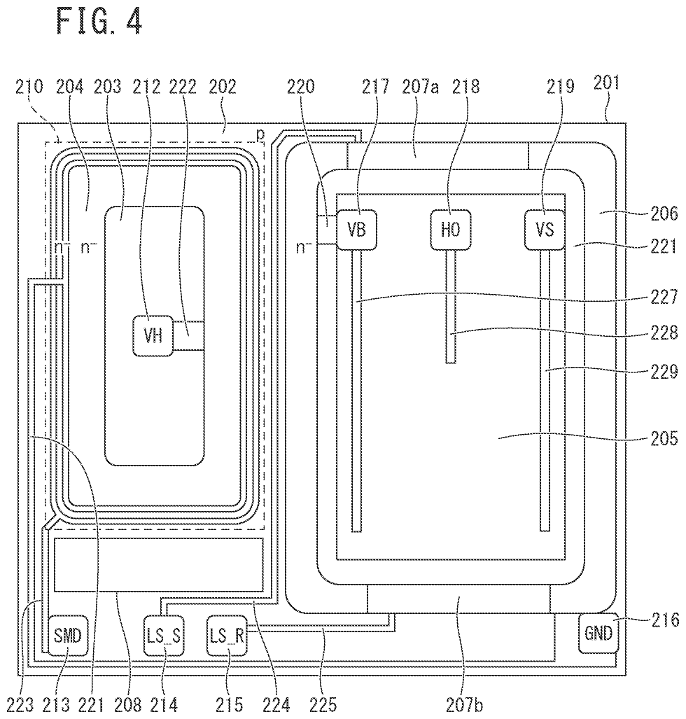

Here is a description of a semiconductor device according to a comparative example. As illustrated in FIG. 4, the semiconductor device according to the comparative example is the same as the semiconductor device according to the first embodiment illustrated in FIG. 2 in that a startup element 210 and a high side circuit region 205 are provided on the same high voltage semiconductor chip 201. However, the semiconductor device according to the comparative example is different from the semiconductor device according to the first embodiment in that the startup element 210 and the high side circuit region 205 are isolated by a p-type ground potential region 202 and respectively are located in separate regions as individual elements. A protection element region 208 is provided adjacent to the startup element 210 and the high side circuit region 205.

A VH pad 212 is connected to a drain region of the startup element 210 via a metal wiring 222 and a metal wiring 203. An SMD pad 213 is connected to a source region of the startup element 210 via a metal wiring 223. An LS_S pad 214 is connected to a level shift element 207a via a metal wiring 224. An LS_R pad 215 is connected to a level shift element 207b via a metal wiring 225. A GND pad 216 is connected to the ground potential region 202 and a gate electrode of the startup element 210 via a metal wiring 226.

A VB pad 217 is connected to an outer peripheral portion of the high side circuit region 205 via a metal wiring 220 and a metal wiring 221. The VB pad 217 is electrically connected to the high side circuit region 205 via a metal wiring 227.

An HO pad 218 is electrically connected to the high side circuit region 205 via a metal wiring 228. A VS pad 219 is electrically connected to the high side circuit region 205 via a metal wiring 229.

In the semiconductor device according to the comparative example, the startup element 210 and the high side circuit region 205 are isolated by the ground potential region 202 and respectively are located in the separate regions as the individual elements. Therefore, chip shrinkage is difficult. On the other hand, according to the semiconductor device provided by the first embodiment, as illustrated in FIG. 2 and FIG. 3, the startup element 10 is provided in the part of the voltage blocking areas 4 and 6 surrounding the high side circuit region 5, and the voltage blocking area 4 on the startup element 10 side and the voltage blocking area 6 on the high side circuit region 5 side are isolated by the isolation regions 31 and 32 and the floating potential region 3. This allows for integration of the high voltage devices to which the VB and VH potentials, which are two different high potentials, are applied, thereby achieving a significant reduction in chip size.

### Second Embodiment

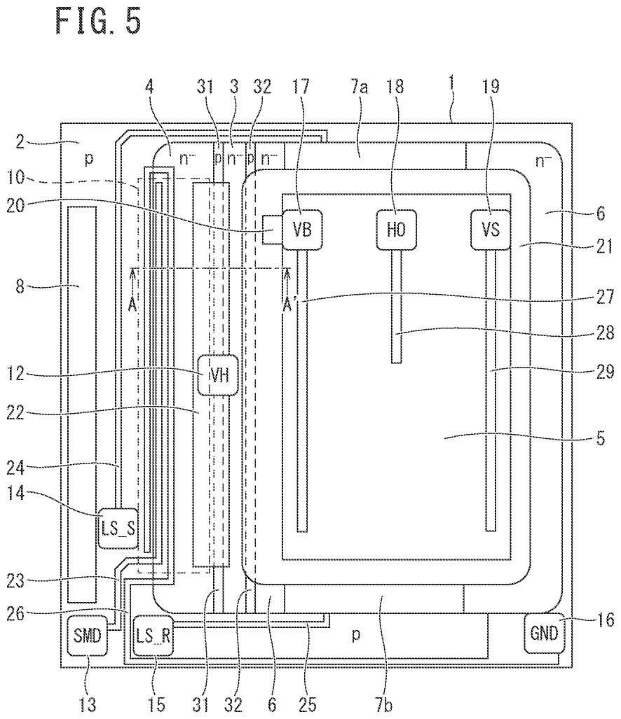

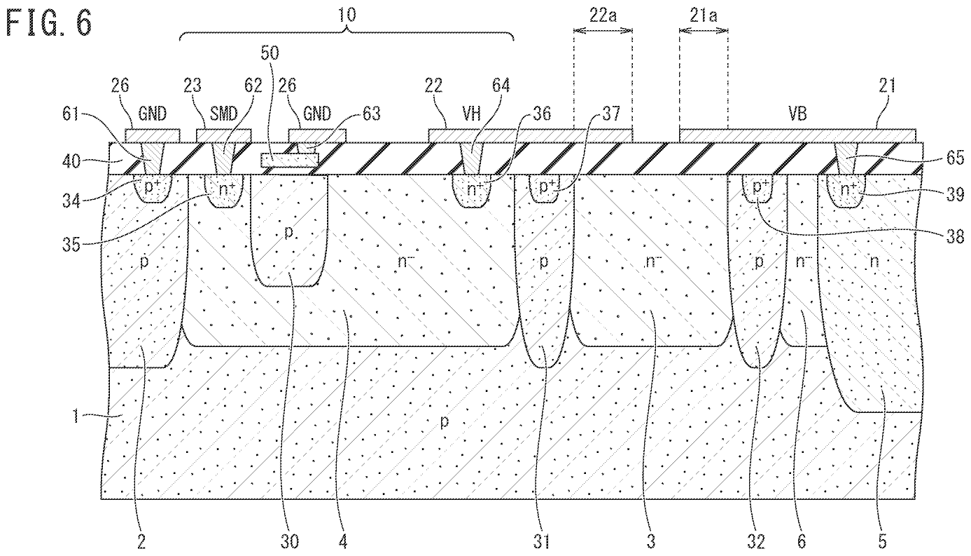

FIG. 5 is a plan view of a semiconductor device according to a second embodiment, and FIG. 6 is a sectional view taken along line A-A′ of FIG. 5. As illustrated in FIG. 5 and FIG. 6, the semiconductor device according to the second embodiment is different from the semiconductor device according to the first embodiment illustrated in FIG. 2 and FIG. 3 in that the metal wiring 22 connected to the VH pad 12 and the metal wiring 21 connected to the VB pad 17 include overhanging portions 22a and 21a that extend horizontally to the floating potential region 3 side and overhang above the floating potential region 3 via the insulating film 40. Other configurations of the semiconductor device according to the second embodiment are substantially the same as those of the semiconductor device according to the first embodiment, and therefore duplicate descriptions are omitted.

According to the semiconductor device provided by the second embodiment, chip size reduction can be achieved while maintaining breakdown voltage, as in the semiconductor device according to the first embodiment. Additionally, since the metal wiring 22 connected to the VH pad 12 and the metal wiring 21 connected to the VB pad 17 overhang above the floating potential region 3 via the insulating film 40, the potential of the floating potential region 3 is easily increased when the VH potential is applied to the VH pad 12 or when the VB potential is applied to the VB pad 17, thus facilitating depletion of the lower parts of the isolation regions 31 and 32.

### Third Embodiment

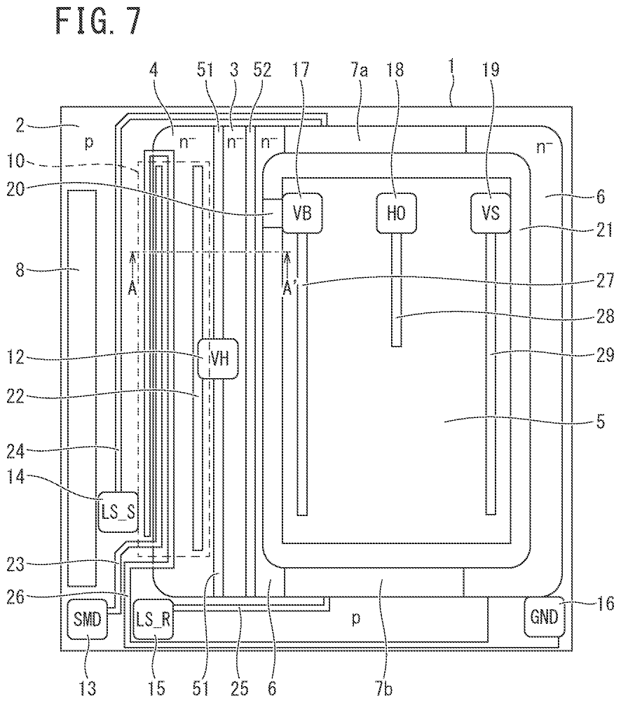

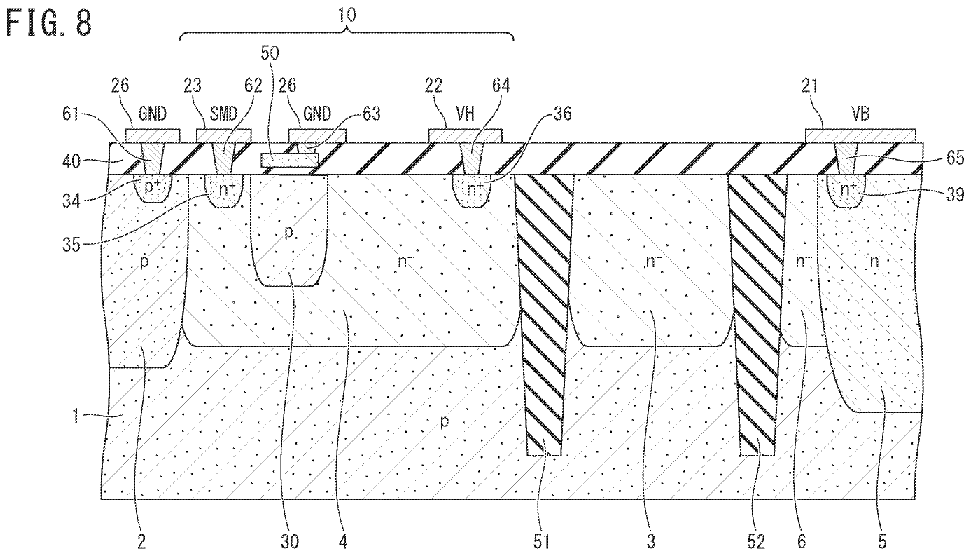

FIG. 7 is a plan view of a semiconductor device according to a third embodiment, and FIG. 8 is a sectional view taken along line A-A′ of FIG. 7. As illustrated in FIG. 7 and FIG. 8, the semiconductor device according to the third embodiment is different from the semiconductor device according to the first embodiment illustrated in FIG. 2 and FIG. 3 in that isolation regions 51 and 52 are constituted by deep trench isolation (DTI) trench grooves. Insides of the trench grooves of the isolation regions 51 and 52 are filled with an insulating film such as, for example, an LP-TEOS film or a polysilicon film. Bottom portions of the isolation regions 51 and 52 reach the p-type semiconductor base body 1. Other configurations of the semiconductor device according to the third embodiment are substantially the same as those of the semiconductor device according to the first embodiment, and therefore duplicate descriptions are omitted.

According to the semiconductor device provided by the third embodiment, even when the isolation regions 51 and 52 are constituted by the DTI trench grooves, a depletion layer of a diode constituted by the floating potential region 3 and the p-type semiconductor base body 1 and a depletion layer extending from the n⁻-type voltage blocking area 4 or the n⁻-type voltage blocking area 6 overlap each other in regions under the isolation regions 51 and 52 formed therebetween to allow for entire depletion when the VH or VB potential goes into a high voltage, thereby achieving a reduction in chip size while maintaining breakdown voltage. Note that even in the semiconductor device according to the third embodiment, the metal wiring 22 connected to the VH pad 12 and the metal wiring 21 connected to the VB pad 17 may extend to the floating potential region 3 side and overhang above the floating potential region 3 via the insulating film 40, as in the semiconductor device according to the second embodiment illustrated in FIG. 5 and FIG. 6. Additionally, one of the two isolation regions 51 and 52 may be constituted by a p-type diffusion region, and the other one thereof may be constituted by a DTI trench groove.

### Fourth Embodiment

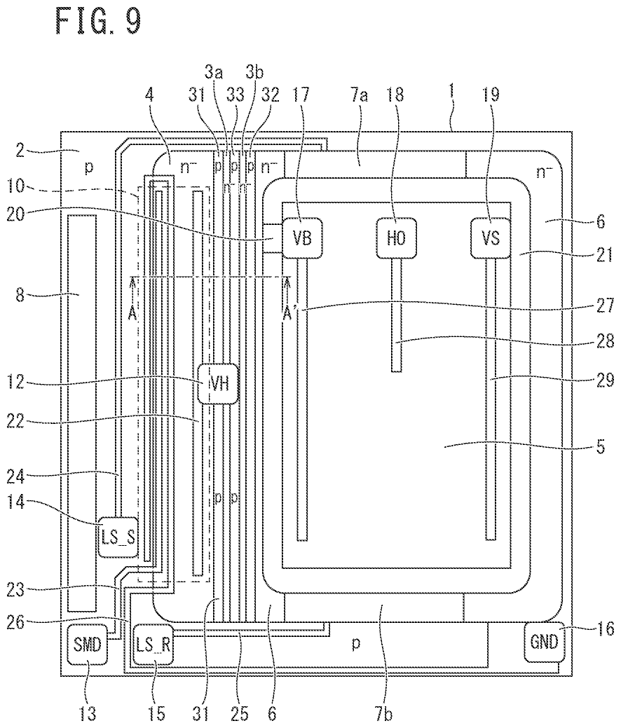

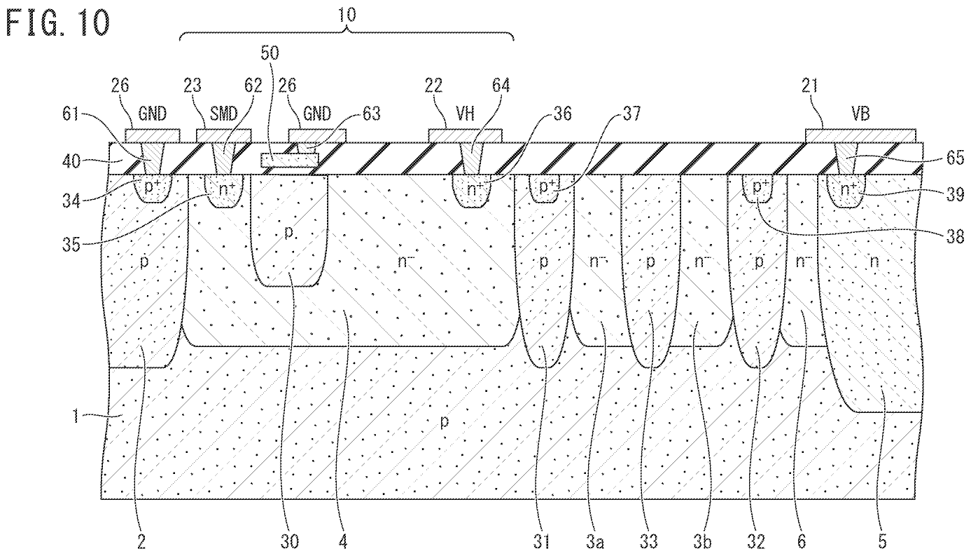

FIG. 9 is a plan view of a semiconductor device according to a fourth embodiment, and FIG. 10 is a sectional view taken along line A-A′ of FIG. 9. As illustrated in FIG. 9 and FIG. 10, the semiconductor device according to the fourth embodiment is different from the semiconductor device according to the first embodiment illustrated in FIG. 2 and FIG. 3 in that there are provided triple isolation regions 31 to 33.

For example, the isolation regions 31 to 33 are constituted by p-type diffusion layers. Note that the isolation regions 31 to 33 may be constituted by DTI regions. Between the isolation regions 31 and 33 is provided an n⁻-type floating potential region (fifth region) 3a at floating potential without being fixed to a specific potential. Between the isolation regions 32 and 33 is provided an n⁻-type floating potential region (fourth region) 3b at floating potential without being fixed to a specific potential. As in the isolation regions 31 and 32, an upper part of the isolation region 33 may also be provided with a pt-type inversion prevention region. Other configurations of the semiconductor device according to the fourth embodiment are substantially the same as those of the semiconductor device according to the first embodiment, and therefore duplicate descriptions are omitted.

According to the semiconductor device provided by the fourth embodiment, even when the triple isolation regions 31 to 33 are provided, chip size reduction can be achieved while maintaining breakdown voltage, as in the semiconductor device according to the first embodiment. Note that even in the semiconductor device according to the fourth embodiment, the metal wiring 22 connected to the VH pad 12 and the metal wiring 21 connected to the VB pad 17 may extend to the floating potential region 3a and 3b sides and overhang above the floating potential regions 3a and 3b via the insulating film 40, as in the semiconductor device according to the second embodiment illustrated in FIG. 5 and FIG. 6. Additionally, although the semiconductor device according to the fourth embodiment has exemplified the case where the triple isolation regions 31 to 33 are provided, quadruple or more isolation regions may be provided.

### Fifth Embodiment

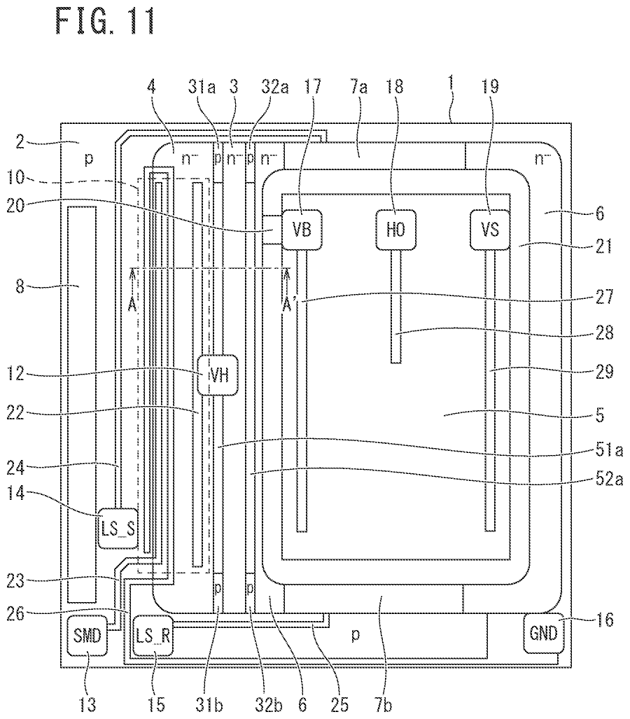

As illustrated in FIG. 11, a semiconductor device according to a fifth embodiment is different from the semiconductor device according to the first embodiment illustrated in FIG. 2 in that each of double isolation regions (31a, 31b, and 51a) and (32a, 32b, and 52a) is constituted by a combination of different structures.

The isolation region (31a, 31b, and 51a) includes a central side isolation portion 51a provided adjacent to the startup element 10, an end side isolation portion 31a connected to one end side of the central side isolation portion 51a, and an end side isolation portion 31b connected to an other end side of the central side isolation portion 51a. The isolation region (32a, 32b, and 52a) includes a central side isolation portion 52a provided to be opposite to and parallel to the central side isolation portion 51a, an end side isolation portion 32a connected to one end side of the central side isolation portion 52a, and an end side isolation portion 32b connected to an other end side of the central side isolation portion 52a.

For example, the central side isolation portions 51a and 52a are constituted by DTI trench grooves, and the end side isolation portions 31a, 31b, 32a, and 32b are constituted by p-type diffusion layers. Other configurations of the semiconductor device according to the fifth embodiment are substantially the same as those of the semiconductor device according to the first embodiment, and therefore duplicate descriptions are omitted.

According to the semiconductor device provided by the fifth embodiment, even when each of the two isolation regions (31a, 31b, and 51a) and (32a, 32b, and 52a) is constituted by the combination of different structures, chip size reduction can be achieved while maintaining breakdown voltage, as in the semiconductor device according to the first embodiment. Note that even in the semiconductor device according to the fifth embodiment, the metal wiring 22 connected to the VH pad 12 and the metal wiring 21 connected to the VB pad 17 may extend to the floating potential region 3 side and overhang above the floating potential region 3 via the insulating film 40, as in the semiconductor device according to the second embodiment illustrated in FIG. 5 and FIG. 6.

### Sixth Embodiment

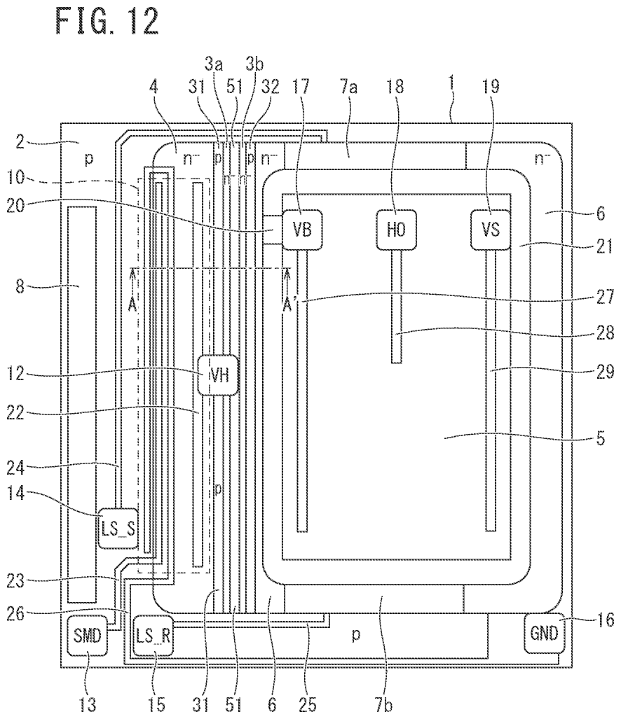

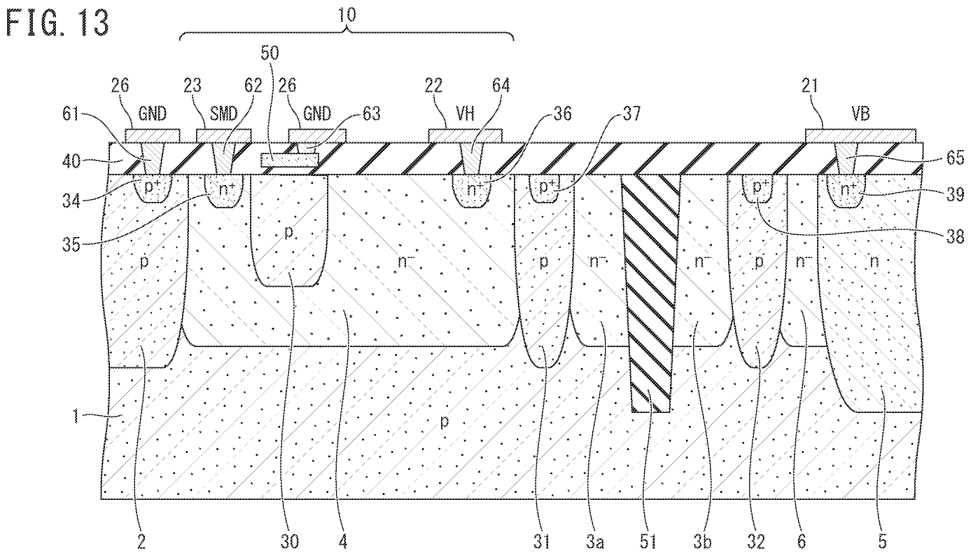

FIG. 12 is a plan view of a semiconductor device according to a sixth embodiment, and FIG. 13 is a sectional view taken along line A-A′ of FIG. 12. As illustrated in FIG. 12 and FIG. 13, the semiconductor device according to the sixth embodiment is different from the semiconductor device according to the first embodiment illustrated in FIG. 2 in that there are provided triple isolation regions 31, 32, and 51, and the isolation region 51, which is one of the triple isolation regions 31, 32, and 51, is different in structure from the other isolation regions 31 and 32.

For example, of the triple isolation regions 31, 32 and 51, the isolation region 51 in a center is constituted by a DTI trench groove, and the isolation regions 31 and 32 adjacent to the isolation region 51, respectively, are constituted by p-type diffusion layers. Other configurations of the semiconductor device according to the sixth embodiment are substantially the same as those of the semiconductor device according to the first embodiment, and therefore duplicate descriptions are omitted.

According to the semiconductor device provided by the sixth embodiment, even when the triple isolation regions 31, 32, and 51 are provided and the isolation region 51 being one of the triple isolation regions 31, 32, and 51 is different in structure from the other isolation regions 31 and 32, chip size reduction can be achieved while maintaining breakdown voltage, as in the semiconductor device according to the first embodiment. Note that even in the semiconductor device according to the sixth embodiment, the metal wiring 22 connected to the VH pad 12 and the metal wiring 21 connected to the VB pad 17 may extend to the floating potential regions 3a and 3b sides and overhang above the floating potential regions 3a and 3b via the insulating film 40, as in the semiconductor device according to the second embodiment illustrated in FIG. 5 and FIG. 6.

### Other Embodiments

As described above, the invention has been described according to the first to sixth embodiments, but it should not be understood that the description and drawings implementing a portion of this disclosure limit the invention. Various alternative embodiments of the present invention, examples, and operational techniques will be apparent to those skilled in the art from this disclosure.

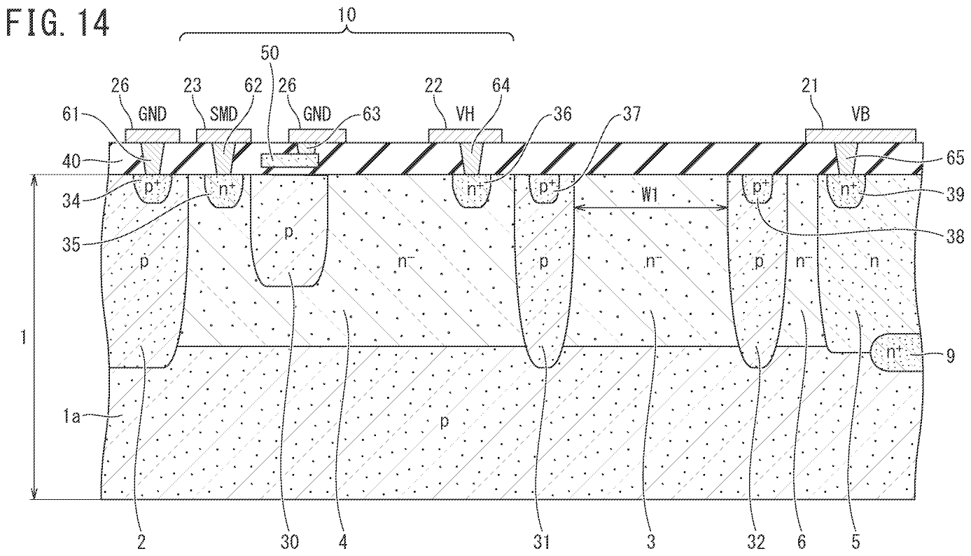

For example, the semiconductor devices according to first to sixth embodiments have been described by exemplifying the structure in which the n-type diffusion layers such as the floating potential region 3, the voltage blocking areas 4 and 6, and the n-type well region being the high side circuit region 5 are formed in the upper part of the p-type semiconductor base body 1. However, the present invention is not limited thereto. For example, as illustrated in FIG. 14, n⁻-type epitaxial growth layers (3, 4, and 6) may be grown on a p-type semiconductor substrate 1a so that the semiconductor base body 1 may be constituted by the p-type semiconductor substrate 1a and the n⁻-type epitaxial growth layers (3, 4, and 6). The n⁻-type epitaxial growth layers (3, 4, and 6) are partitioned by the p-type ground potential region 2, the p-type isolation regions 31 and 32, and the n-type high side circuit region 5, which are diffusion layers, to constitute the floating potential region 3 and the voltage blocking areas 4 and 6, respectively. Additionally, at a bottom portion of the high side circuit region 5, i.e., between the p-type semiconductor base body 1 and the high side circuit region 5 may be provided an n⁺-type buried layer 9 having a higher impurity concentration than the high side circuit region 5. The buried layer 9 is constituted by a diffusion layer doped with an n-type impurity such as, for example, antimony (Sb), phosphorus (P), or arsenic (As).

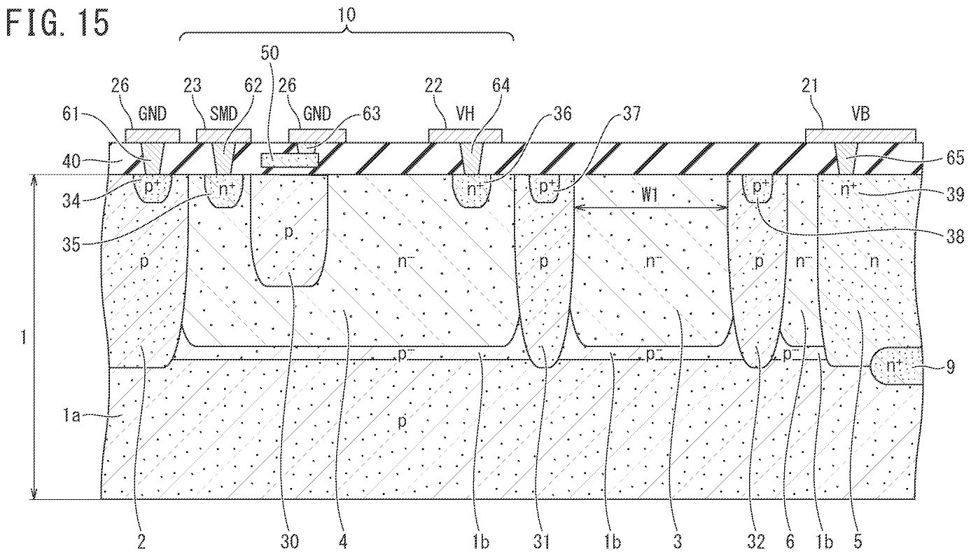

Alternatively, as illustrated in FIG. 15, a p⁻-type epitaxial growth layer 1b may be grown on a p-type semiconductor base body 1a so that the semiconductor base body 1 may be constituted by the p-type semiconductor base body 1a and the p⁻-type epitaxial growth layer 1b. Then, n-type diffusion layers may be formed in the p⁻-type epitaxial growth layer 1b to constitute the floating potential region 3, the voltage blocking areas 4 and 6, and the high side circuit region 5, respectively. Additionally, p-type diffusion layers may be formed in the p⁻-type epitaxial growth layer 1b to constitute the ground potential region 2 and the isolation regions 31 and 32. Between the p-type semiconductor base body 1a and the high side circuit region 5 may be provided the n⁺-type buried layer 9 having a higher impurity concentration than the high side circuit region 5.

In addition, the semiconductor devices according to first to sixth embodiments have been described by using the example where the startup element 10 and the high side circuit region 5 are formed in the same high breakdown voltage semiconductor chip 1. However, the startup element 10 and the high side circuit region 5 are merely illustrative components. In other words, the present invention is applicable to cases where a plurality of structures that perform high voltage behaviors independent of each other is formed in the same high breakdown voltage semiconductor chip.

The respective configurations disclosed in the first to sixth embodiments of the present invention and the respective modified examples can be combined together as necessary within a range without contradicting each other. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present Specification.

What is claimed is:

1. A semiconductor device comprising:
a semiconductor base body;
a first region of a first conductivity type selectively provided in an upper part of the semiconductor base body;
a second region of a second conductivity type provided in contact with the first region in the upper part of the semiconductor base body;
a third region of the second conductivity type provided away from the second region in the upper part of the semiconductor base body;
a fourth region of the second conductivity type provided between the second region and the third region in the upper part of the semiconductor base body;
a first isolation region provided between the second region and the fourth region; and
a second isolation region provided between the third region and the fourth region.

2. The semiconductor device of claim 1, wherein each of the first and second isolation regions is a diffusion layer of the first conductivity type.

3. The semiconductor device of claim 2, further comprising an inversion prevention layer of the first conductivity type provided in an upper part of each of the first and second isolation regions and having a higher impurity concentration than the first and second isolation regions.

4. The semiconductor device of claim 1, wherein each of the first and second isolation regions is a trench groove.

5. The semiconductor device of claim 1, wherein a part of each of the first and second isolation regions is constituted by a diffusion layer of the first conductivity type, and an other part of each of the first and second isolation regions is constituted by a trench groove.

6. The semiconductor device of claim 1, wherein the fourth region has a width of 50 μm or more.

7. The semiconductor device of claim 1, further comprising:
a first wiring electrically connected to the second region, a first potential being applied to the first wiring; and
a second wiring electrically connected to the third region, a second potential different from the first potential being applied to the second wiring,
wherein the fourth region is a region having a floating potential.

8. The semiconductor device of claim 7, wherein
the first wiring includes a first overhanging portion overhanging above the fourth region from the first isolation region side, and
the second wiring includes a second overhanging portion overhanging above the fourth region from the second isolation region side.

9. The semiconductor device of claim 1, further comprising:
a fifth region of the second conductivity type provided between the fourth region and the first isolation region in the upper part of the semiconductor base body; and
a third isolation region provided between the fourth region and the fifth region.

10. The semiconductor device of claim 9, wherein the third isolation region has a different structure from the first and second isolation regions.

11. The semiconductor device of claim 1, wherein the first and second isolation regions each have a linear planar shape extending parallel to each other, longitudinal ends of the planar shapes of the first and second isolation regions being in contact with the first region.

12. The semiconductor device of claim 1, further comprising a sixth region of the second conductivity type provided in contact with the third region to surround the third region besides at least between the second isolation region and the third region in the upper part of the semiconductor base body, the sixth region having a lower impurity concentration than the third region.

13. The semiconductor device of claim 12, further comprising:
a seventh region of the second conductivity type provided in an upper part of the second region and having a higher impurity concentration than the second region; and
an eighth region of the second conductivity type provided away from the seventh region in the upper part of the second region and having a higher impurity concentration than the second region.

14. The semiconductor device of claim 13, wherein
the third region is a region including an electrode pad connected to a low potential side terminal of a high potential side power switching element of two power switching elements connected in series to form a gate driver circuit,
the seventh region is a carrier supply region of a startup element, and
the eighth region is a carrier reception region of the startup element, and is provided between the seventh region and the first isolation region.

15. The semiconductor device of claim 14, wherein the first potential is applied to the carrier reception region.

16. The semiconductor device of claim 14, wherein the second potential is a potential of a power supply using a potential applied to the electrode pad as a reference potential.
